(19) United States
(12) Patent Application Publication
(10) Pub. No.: US 2026/0182426 A1
(43) Pub. Date: Jun. 25, 2026

(54) PACKAGE SUBSTRATE AND SEMICONDUCTOR PACKAGE INCLUDING THE SAME

(71) Applicant: SAMSUNG ELECTRONICS CO., LTD., Suwon-si (KR)

(72) Inventors: Soonil JUNG, Suwon-si (KR); Wooyeol LEE, Suwon-si (KR)

(73) Assignee: SAMSUNG ELECTRONICS CO., LTD., Suwon-si (KR)

(21) Appl. No.: 19/365,734

(22) Filed: Oct. 22, 2025

(30) Foreign Application Priority Data
Dec. 9, 2024 (KR) 10-2024-0181255

(51) Int. Cl. H01L 23/498; H01L 23/00; H01L 23/31

(52) U.S. Cl. CPC H10W 70/685; H10W 70/65; H10W 74/117; H10W 90/701; H10W 72/884; H10W 90/734; H10W 90/754

(57) ABSTRACT

A package substrate includes a first protective pattern, an insulation layer disposed on the first protective pattern and having a recess, and a first wiring buried in a portion of the insulation layer at which the recess is formed. A conductive pad is disposed on the first wiring, with a lower surface of the conductive pad positioned higher than or coplanar with a lower surface of the recess. A second protective pattern is formed on the insulation layer and includes an opening connected to the recess.

### CROSS-REFERENCE TO RELATED APPLICATION

This application claims priority under 35 U.S.C. § 119 to Korean Patent Application No. 10-2024-0181255, filed on Dec. 9, 2024 in the Korean Intellectual Property Office (KIPO), the contents of which are herein incorporated by reference in their entirety.

### BACKGROUND

### 1. Field

Example embodiments relate to a package substrate, a semiconductor package including the same, and a method of manufacturing the package substrate.

### 2. Description of the Related Art

A semiconductor package includes a package substrate and a semiconductor chip on the package substrate, and the package substrate includes insulation layers stacked in a vertical direction and wirings and vias in the insulation layers. A conductive substrate pad is disposed on some of the wirings, and is electrically connected to a conductive chip pad of the semiconductor chip through, e.g., a bonding wire. If the bonding wire contacts the conductive substrate pad well, the electrical signals may be transmitted well.

### SUMMARY

Example embodiments provide a package substrate having enhanced electrical characteristics.

Example embodiments provide a semiconductor package having enhanced electrical characteristics.

Example embodiments provide a method of manufacturing a package substrate having enhanced electrical characteristics.

According to example embodiments, there is provided a package substrate. The package substrate may include a first protective pattern, an insulation layer on the first protective pattern and having a recess thereon, a first wiring buried at a portion of the insulation layer on which the recess is disposed, a conductive pad on the first wiring and having a lower surface higher than or coplanar with a lower surface of the recess, and a second protective pattern on the insulation layer and having an opening connected to the recess.

According to example embodiments, there is provided a package substrate. The package substrate may include a first protective pattern, an insulation layer structure including insulation layers stacked in a vertical direction on the first protective pattern, a wiring structure including wirings disposed in the vertical direction in the first protective pattern and the insulation layer structure, and a second protective pattern on the insulation layer structure and the wiring structure. First and second wirings among the wirings may be buried in a first insulation layer that is an uppermost one of the insulation layers, and an upper surface of each of the first and second wirings may be lower than an upper surface of the first insulation layer. The second protective pattern may cover the upper surface of the first wiring and expose the upper surface of the second wiring. The package substrate may further include a first conductive pad on the second wiring having an upper surface lower than the upper surface of the first insulation layer. A portion of the first insulation layer adjacent to the first conductive pad may have a recess exposing a sidewall of the first conductive pad.

According to example embodiments, there is provided a semiconductor package. The semiconductor package may include package substrate, a semiconductor chip, a bonding wire and a molding member. The package substrate may include a first protective pattern, an insulation layer on the first protective pattern and having a recess thereon, a first wiring buried at a portion of the insulation layer on which the recess is disposed, a first conductive pad on the first wiring and having a lower surface higher than or coplanar with a lower surface of the recess, and a second protective pattern on the insulation layer and having an opening connected to the recess. The semiconductor chip may be disposed on the package substrate, and may have a second conductive pad. The bonding wire may contact an upper surface of the first conductive pad and an upper surface of the second conductive pad. The molding member may be disposed on the package substrate. The molding member may cover the semiconductor chip and the bonding wire, and may fill the recess and the opening.

According to example embodiments, a method of manufacturing a package substrate is provided. In the method, a first wiring may be formed in a first insulation layer. An upper surface of the first wiring may be lower than an upper surface of the first insulation layer. A conductive pad may be formed on the first wiring. A protective pattern may be formed on the first insulation layer having an opening exposing an upper surface of the conductive pad. An upper portion of the first insulation layer not covered by the protective pattern may be removed to form a recess exposing a sidewall of the conductive pad.

The package substrate in accordance with example embodiments may not be damaged during a wire bonding process, and the electrical connection between the package substrate and the semiconductor chip mounted thereon may be good.

### BRIEF DESCRIPTION OF THE DRAWINGS

FIG. 1 is a cross-sectional view illustrating a package substrate in accordance with example embodiments.

FIGS. 2 to 6 are cross-sectional views illustrating a method of manufacturing a package substrate in accordance with example embodiments.

FIG. 7 is a cross-sectional view illustrating a package substrate in accordance with example embodiments.

FIG. 8 is a cross-sectional view illustrating a semiconductor package in accordance with example embodiments.

### DETAILED DESCRIPTION OF EXAMPLE EMBODIMENTS

Hereinafter, example embodiments will be explained in detail with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, a direction parallel to an upper surface or a lower surface of a protective pattern or an insulation layer may be referred to as a horizontal direction, and a direction perpendicular to the upper surface or the lower surface of the protective pattern or the insulation layer may be referred to as a perpendicular direction.

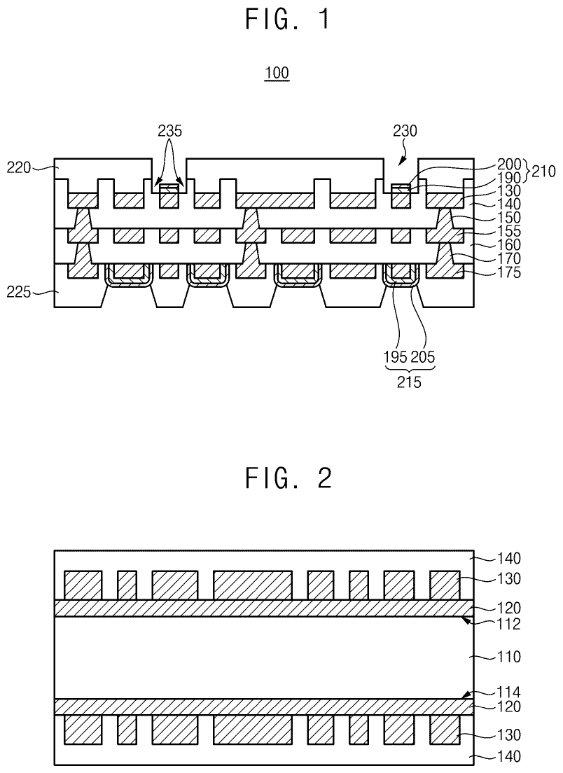

FIG. 1 is a cross-sectional view illustrating a package substrate in accordance with example embodiments.

Referring to FIG. 1, a package substrate 100 may include first and second protective patterns 220 and 225, first to second insulation layers 140 and 160, first and second vias 150 and 170, first to third wirings 130, 155 and 175, and first and second conductive pads 210 and 215.

In example embodiments, the second insulation layer 160 may be disposed on the second protective pattern 225, and the first insulation layer 140 may be disposed on the second insulation layer 160. FIG. 1 shows two second insulation layers, that is, the second insulation layer 160 and the first insulation layer 140 are stacked in the vertical direction on the second protective pattern 225, however, the inventive concept is not limited thereto, and more than two insulation layers may be stacked in the vertical direction on the second protective pattern 225. The second insulation layer 160 and the first insulation layer 140 stacked in the vertical direction may collectively form an insulation layer structure.

Each of the first and second insulation layers 140 and 160 may include an insulating material, e.g., prepreg (PPG), Ajinomoto build-up film (ABF), etc. In an example embodiment, the first and second insulation layers 140 and 160 may include substantially the same material as each other to be merged with each other, and thus may not be differentiated from each other. Alternatively, the first and second insulation layers 140 and 160 may include different materials from each other, or may include substantially the same material as each other but may be differentiated from each other by a natural oxide layer therebetween.

The third wiring 175 may be disposed on a lower surface of the second insulation layer 160, and a plurality of third wirings 175 may be spaced apart from each other in the horizontal direction. In example embodiments, a sidewall and a lower surface of a first one of the third wirings 175 may be covered by the second protective pattern 225, and the second conductive pad 215 may be disposed on a sidewall and a lower surface of a second one of the third wirings 175.

The second conductive pad 215 may include second and fourth conductive patterns 195 and 205 sequentially stacked from the sidewall and the lower surface of the second one of the third wirings 175. A sidewall of the second conductive pad 215 may be covered by the second protective pattern 225, and a lower surface of the second conductive pad 215 may be exposed.

The second wiring 155 may contact a lower surface of the first insulation layer 140, and a plurality of second wirings 155 may be spaced apart from each other in the horizontal direction. A sidewall and a lower surface of each of the second wirings 155 may be covered by the second insulation layer 160.

The second via 170 may extend through a lower portion of the second insulation layer 160, and may contact an upper surface of the first one of the third wirings 175 and a lower surface of a first one of the second wirings 155. In example embodiments, a plurality of second vias 170 may be spaced apart from each other in the horizontal direction.

In example embodiments, the first wiring 130 may extend through an upper portion of the first insulation layer 140, and a plurality of first wirings 130 may be spaced apart from each other in the horizontal direction. In example embodiments, an upper surface of each of the first wirings 130 may be lower than an upper surface of the first insulation layer 140. Lower surfaces of the first wirings 130 may be substantially coplanar with each other, and upper surfaces of the first wirings 130 may be substantially coplanar with each other.

The first via 150 may extend through a lower portion of the first insulation layer 140, and may contact an upper surface of the first one of the second wirings 155 and a lower surface of a first one of the first wirings 130. In example embodiments, a plurality of first vias 150 may be spaced apart from each other in the horizontal direction.

The first to third wirings 130, 155 and 175 and the first and second vias 150 and 170 may collectively form a wiring structure. However, FIG. 1 shows a non-limiting embodiment of the wiring structure, and the wiring structure may include wirings and vias that are disposed at a plurality of levels, respectively.

The first protective pattern 220 may be disposed on an upper surface of the first insulation layer 140, and may cover an upper surface of the first one of the first wirings 130, and may include an eighth opening 230 overlapping a second one of the first wirings 130 in the vertical direction. In example embodiments, a second recess 235 may be disposed at a portion of the first insulation layer 140 under the eighth opening 230, and may expose an upper surface and a sidewall of the first conductive pad 210 on an upper surface of the second one of the first wirings 130. The second recess 235 may be connected to the eighth opening 230.

In example embodiments, sidewalls in the horizontal direction of the eighth opening 230 and the second recess 235 may be aligned with each other in the vertical direction.

In example embodiments, a width in the horizontal direction of each of the eighth opening 230 and the second recess 235 may be greater than widths in the horizontal direction of the second one of the first wirings 130 and the first conductive pad 210. In example embodiments, a lower surface of the second recess 235 may be substantially coplanar with a lower surface of the first conductive pad 210 or the upper surface of the second one of the first wirings 130.

The first conductive pad 210 may include first and third conductive patterns 190 and 200 sequentially stacked in the vertical direction on the upper surface of the second one of the first wirings 130. In example embodiments, the width in the horizontal direction of the first conductive pad 210 may be substantially the same as the width in the horizontal direction of the second one of the first wirings 130, and a sidewall of the first conductive pad 210 may be aligned with a sidewall of the second one of the first wirings 130 under the first conductive pad 210 in the vertical direction.

In example embodiments, each of the first and third conductive patterns 190 and 200 may be substantially flat, and may be lower than an upper surface of the first insulation layer 140 on which the second recess 235 is formed.

The first conductive pad 210 may serve as, e.g., a bonding finger in the package substrate 100.

A thickness in the vertical direction of each of the first wirings 130 may be in a range of about 8 μm to about 20 μm, a thickness in the vertical direction of the first conductive pattern 190 may be in a range of about 2 μm to about 10 μm, and a thickness in the vertical direction of the third conductive pattern 200 may be in a range of about 0.3 μm to about 1.0 μm. Thus, a thickness in the vertical direction of the first conductive pad 210 including the first and third conductive patterns 190 and 200 may be in a range of about 2.3 μm to about 11.0 μm.

In example embodiments, a thickness of the second conductive pattern 195 may be substantially the same as the thickness in the vertical direction of the first conductive pattern 190, and a thickness of the fourth conductive pattern 205 may be substantially the same as the thickness in the vertical direction of the third conductive pattern 200.

Each of the first to third wirings 130, 155 and 175 and the first and second vias 150 and 170 may include a metal, e.g., copper, aluminum, etc., each of the first and second conductive patterns 190 and 195 may include a metal, e.g., nickel, and each of the third and fourth conductive patterns 200 and 205 may include a metal, e.g., gold.

Each of the first and second protective patterns 220 and 225 may include, e.g., solder resist (SR).

In the package substrate 100 in accordance with example embodiments, the upper surface of the first one of the first wirings 130 covered by the first protective pattern 220 may be lower than an upper surface of a portion of the insulation layer 140 adjacent to the first one of the first wirings 130, while the upper surface of the second one of the first wirings 130 not covered by the first protective pattern 220 may be substantially coplanar with an upper surface of a portion of the insulation layer 140 adjacent to the second one of the first wirings 130. The widths in the horizontal direction of the eighth opening 230 overlapping the second one of the first wirings 130 and the second recess 235 under the eighth opening 230 may be greater than the width in the horizontal direction of the second one of the first wirings 130.

Thus, the upper surface and the sidewall of the first conductive pad 210 that may be disposed on the second one of the first wirings 130 and serve as a bonding finger may not be covered by the first insulation layer 140 and the first protective pattern 220, but may be exposed outwardly. Accordingly, after mounting a semiconductor chip on the package substrate 100, when a wire bonding process for electrically connecting the semiconductor chip and the first conductive pad 210 is performed, an upper portion of the first insulation layer 140 may not be damaged by a capillary used in the wire bonding process.

If, for example, the first conductive pad 210 is disposed on the first wiring 130 buried in the upper portion of the first insulation layer 140, and the upper surface of the first conductive pad 210 is lower than the upper surface of the portion of the first insulation layer adjacent to the first conductive pad 210, during the wire bonding process, the portion of the first insulation layer 140 may be damaged by the capillary.

However, in example embodiments, the first conductive pad 210 may be disposed on the first wiring 130 at a portion of the first insulation layer 140 having an upper surface that may be relatively low, and thus, during the wire bonding process, the portion of the first insulation layer 140 may not be damaged by the capillary.

As illustrated below with reference to FIGS. 2 to 6, the first conductive pad 210 may be formed only on the upper surface of the first wiring 130, and may have a substantially flat upper surface. Thus, a bonding wire that may be formed by a wire bonding process may be formed on the substantially flat upper surface, so as to contact the upper surface of the first conductive pad 210 over a sufficiently large area.

For example, as the second conductive pad 215 on a surface of the third wiring 175 protruding from the lower surface of the second insulation layer 160, if the first conductive pad 210 is formed on a surface, that is, an upper surface and a sidewall of the first wirings 130 protruding from the upper surface of the first insulation layer 140, during the formation of the first conductive pad 210, a portion of the first conductive pad 210 on an upper surface of an edge portion of the first wiring 130 may not be flat but rounded, so that a bonding wire that may be formed on the first conductive pad 210 by a wire bonding process may not contact the first conductive pad 210 over a sufficiently large area.

However, in example embodiments, the first conductive pad 210 may be formed only on the upper surface of the first wiring 130 buried in the upper portion of the first insulation layer 140 and may have a substantially flat upper surface, so that the bonding wire that may be formed on the first conductive pad 210 by a wire bonding process may contact the first conductive pad 210 over a sufficiently large area.

As a result, the package substrate 100 may not be damaged when the wire bonding process is performed, and an electrical connection between the package substrate 100 and the semiconductor chip mounted thereon may be good.

FIGS. 2 to 6 are cross-sectional views illustrating a method of manufacturing a package substrate in accordance with example embodiments.

Referring to FIG. 2, seed layers 120 may be formed on first and second surfaces 112 and 114, respectively, of a detach core 110 that are opposite to each other in the vertical direction, first wirings 130 may be formed on upper and lower surfaces of the seed layers 120, respectively, and first insulation layers 140 may be formed on the upper and lower surfaces of the seed layers 120, respectively, to cover the first wirings 130.

In an example embodiment, the detach core 110 may include a mixture of, e.g., glass fiber and epoxy resin.

In example embodiments, first masks having first openings may be formed on the upper and lower surfaces of the seed layers 120, respectively, and an electroplating process or an electroless plating process may be performed so that the first wirings 130 may be formed in the first openings, respectively. After forming the first wirings 130, the first masks may be removed. The first insulation layers 140 may be formed by a lamination process or a coating process.

In an example embodiment, a detach adhesion layer may be further formed between the detach core 110 and each of the seed layers 120.

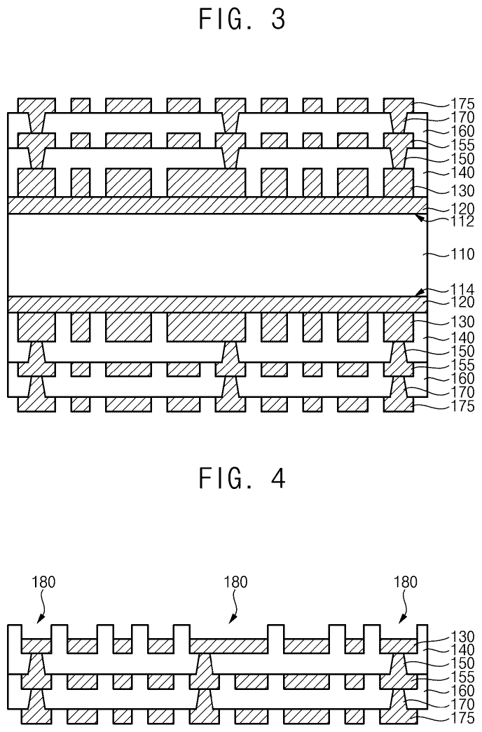

Referring to FIG. 3, upper and lower portions of the first insulation layers 140 may be partially removed to form second openings exposing upper and lower surfaces of the first wirings 130, respectively, second masks having third openings connected to the second openings, respectively, may be formed on upper and lower surfaces of the first insulation layers 140, respectively, an electroplating process or an electroless plating process may be performed so that a first via 150 and a second wiring 155 may be formed in the second and third openings, respectively. After forming the first via 150 and the second wiring 155, the second masks may be removed.

Second insulation layers 160 may be formed on upper and lower surfaces of the first insulation layers 140, respectively, to cover the second wirings 155, upper and lower portions of the second insulation layers 160 may be partially removed to form fourth openings exposing upper and lower surfaces of the second wirings 155, respectively, third masks having fifth openings connected to the fourth openings, respectively, may be formed on upper and lower surfaces of the second insulation layers 160, respectively, an electroplating process or an electroless plating process may be performed so that a second via 170 and a third wiring 175 may be formed in the fourth and fifth openings, respectively. After forming the second via 170 and the third wiring 175, the third masks may be removed.

Referring to FIG. 4, the detach core 110 may be removed so that stack structures on the first and second surfaces 112 and 114, respectively, of the detach core 110 may be separated from each other, and the seed layers 120 of the stack structures may be removed.

In example embodiments, when the seed layers 120 are removed, portions of the first wirings 130 adjacent to the seed layers 120 may also be removed to form first recesses 180. Particularly, when the seed layer 120 included in the stack structure on the second surface 114 of the detach core 110 is removed, an upper portion of the first wiring 130 adjacent to the seed layer 120 may also be removed to form the first recess 180, and likewise, when the seed layer 120 included in the stack structure on the first surface 112 of the detach core 110 is removed, a lower portion of the first wiring 130 adjacent to the seed layer 120 may also be removed to form the first recess 180.

Thus, the first wiring 130 may be buried in the first insulation layer 140. In example embodiments, the first wiring 130 may have a substantially flat upper surface.

Hereinafter, the stack structure on the second surface 114 of the detach core 110 is illustrated.

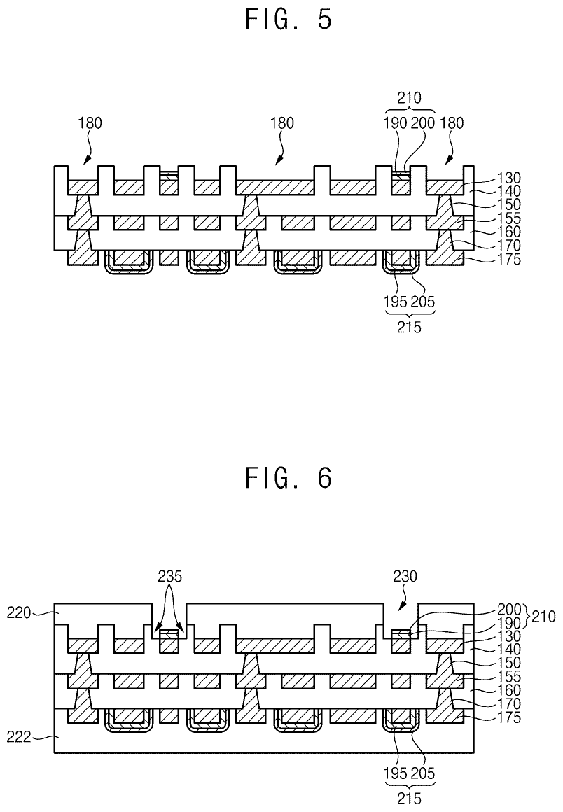

Referring to FIG. 5, fourth and fifth masks having sixth and seventh openings, respectively, may be formed on upper and lower surfaces of the stack structure, an electroplating process or an electroless plating process may be performed to form first and second conductive pads 210 and 215 in the sixth and seventh openings, respectively, and the fourth and fifth masks may be removed.

In example embodiments, the sixth opening may be connected to some of the first recesses 180, and the first conductive pad 210 may be formed on an upper surface of the first wiring 130 in the first recess 180 connected to the sixth opening. In example embodiments, the first conductive pad 210 may have a substantially flat upper surface, and may include first and third conductive patterns 190 and 200 stacked in the vertical direction.

In example embodiments, the seventh opening may expose some of the third wirings 175, and the second conductive pad 215 may be formed on a sidewall and a lower surface of the third wiring 175 exposed by the seventh opening. In example embodiments, the second conductive pad 215 may have a substantially flat upper surface, and may include second and fourth conductive patterns 195 and 205 stacked in the vertical direction.

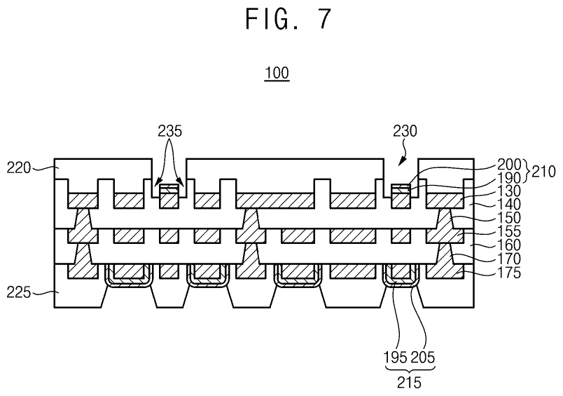

Referring to FIG. 6, a first protective layer and a second protective layer 222 may be formed on upper and lower surfaces, respectively, of the stack structure, the first protective layer may be partially removed to form a first protective pattern 220 having an eighth opening 230 exposing an upper surface of a portion of the first insulation layer 140, and the exposed portion of the first insulation layer 140 may be partially removed to form a second recess 235.

In example embodiments, a lower surface of the second recess 235 may be formed to be substantially coplanar with an upper surface of the first wiring 130, and thus an upper surface and a sidewall of the first conductive pad 210 may be exposed by the second recess 235.

Referring to FIG. 1 again, the second protective layer 222 may be partially removed to form a second protective pattern 225, and thus a lower surface of the second conductive pad 215 may be exposed.

By the above processes, the package substrate may be manufactured.

FIG. 7 is a cross-sectional view illustrating a package substrate in accordance with example embodiments. This package substrate may be substantially the same as or similar to that of FIG. 1, except for the height of the lower surface of the second recess, and thus repeated explanations are omitted herein.

Referring to FIG. 7, the lower surface of the second recess 235 may be lower than the lower surface of the first conductive pad 210 or the upper surface of the first wiring 130, and thus an upper sidewall of the first wiring 130 may be exposed.

In an example embodiment, the lower surface of the second recess 235 may be lower than the upper surface of the first wiring 130 by about 3 μm to about 5 μm.

In some embodiments, the lower surface of the second recess 235 may be substantially coplanar with the lower surface of the first wiring 130. That is, the lower surface of the second recess 235 may be substantially coplanar with the upper surface of the first wiring 130, substantially coplanar with the lower surface of the first wiring 130, or lower than the upper surface of the first wiring 130 and higher than the lower surface of the first wiring 130.

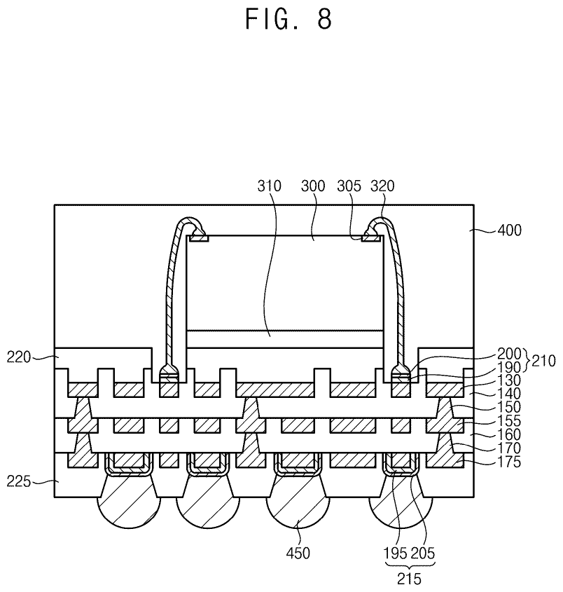

FIG. 8 is a cross-sectional view illustrating a semiconductor package in accordance with example embodiments. The semiconductor package may include the package substrate of FIG. 1, and thus repeated explanations of the package substrate are omitted herein. In some embodiments, the semiconductor package may include the package substrate of FIG. 7.

Referring to FIG. 8, the semiconductor package may include the package substrate 100, a semiconductor chip 300, an adhesion layer 310, a bonding wire 320, a molding member 400 and a conductive connection member 450.

The semiconductor chip 300 may be a logic chip including logic device or a memory chip including a memory device. A third conductive pad 305 may be disposed on a surface of the semiconductor chip 300, and the bonding wire 320 may contact an upper surface of the third conductive pad 305 and the upper surface of the first conductive pad 210 included in the package substrate 100.

The adhesion layer 310 may be interposed between the first protective pattern 220 included in the package substrate 100 and a lower surface of the semiconductor chip 300, and may bond the first protective pattern 220 and the semiconductor chip 300 to each other. The adhesion layer 310 may include, e.g., die attach film (DAF), non-conductive film (NCF), non-conductive paste (NCP), etc.

The molding member 400 may be disposed on the first protective pattern 220 included in the package substrate 100, and may cover the semiconductor chip 300, the adhesion layer 310 and the bonding wire 320. The molding member 400 may include, e.g., epoxy molding compound (EMC).

The conductive connection member 450 may be disposed on a lower surface of the second protective pattern 225 included in the package substrate 100, and may contact a lower surface of the second conductive pad 215. The conductive connection member 450 may be a conductive bump or a conductive ball including, e.g., solder.

As illustrated above with reference to FIG. 1, when the bonding wire 320 is formed to contact the upper surface of the first conductive pad 210 by a wire bonding process using a capillary, the portion of the first insulation layer 140 adjacent to the first conductive pad 210 may not be damaged. Additionally, the bonding wire 320 may contact the flat upper surface of the first conductive pad 210 over a sufficiently large area, the electrical connection between the package substrate 100 and the semiconductor chip 300 may be good.

In a method of manufacturing a package substrate, a first wiring may be formed in a first insulation layer, and an upper surface of the first wiring may be lower than an upper surface of the first insulation layer. A conductive pad may be formed on the first wiring. A protective pattern may be formed on the first insulation layer having an opening exposing an upper surface of the conductive pad. An upper portion of the first insulation layer not covered by the protective pattern may be removed to form a recess exposing a sidewall of the conductive pad.

In example embodiments, a second wiring may be formed in the first insulation layer. The second wiring may be spaced apart from the first wiring in a horizontal direction, and the second wiring may have an upper surface lower than the upper surface of the first insulation layer. The protective pattern may be formed to cover an upper surface of the second wiring.

In example embodiments, a lower surface of the second wiring may be coplanar with a lower surface of the first wiring.

In example embodiments, when the first wiring is formed, a first seed layer may be formed on a first surface of a detach core. The detach core may have the first surface and a second surface that is opposite to the first surface in a vertical direction. A first wiring layer may be formed on the first seed layer. A first insulation layer may be formed on the first surface of the detach core to cover the first wiring layer. The detach core, the first seed layer, and a portion of the first wiring layer adjacent to the first seed layer may be removed.

In example embodiments, when the first seed layer is formed on the first surface of the detach core, a second seed layer may be formed on the second surface of the detach core. When the first wiring layer is formed on the first seed layer, a second wiring layer may be formed on the second seed layer. When the first insulation layer is formed on the first surface of the detach core to cover the first wiring layer, a second insulation layer may be formed on the second surface of the detach core to cover the second wiring layer. When the detach core, the first seed layer, and the portion of the first wiring layer adjacent to the first seed layer are removed, a portion of the second wiring layer adjacent to the second seed layer may be removed.

In example embodiments, when the conductive pad is formed on the first wiring, first and second conductive patterns sequentially stacked in a vertical direction may be formed, and the first and second conductive patterns may include different metals from each other.

In example embodiments, when the conductive pad is formed on the first wiring, the conductive pad may be formed such that an upper surface of the conductive pad may be lower than the upper surface of the first insulation layer.

In example embodiments, a lower surface of the recess may be formed to be coplanar with the upper surface of the first wiring.

In example embodiments, a lower surface of the recess may be formed to be lower than the upper surface of the first wiring.

In example embodiments, when the protective pattern is formed on the first insulation layer, the protective pattern may be formed such that a width of the opening may be formed to be greater than a width of the conductive pad.

In example embodiments, when the conductive pad is formed on the first wiring, the conductive pad may be formed on an upper surface of the first wiring, and the conductive pad may not extend along a sidewall of the first wiring.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A package substrate comprising:
a first protective pattern;
an insulation layer on the first protective pattern, the insulation layer having a recess thereon;
a first wiring buried at a portion of the insulation layer on which the recess is disposed;
a conductive pad on the first wiring, a lower surface of the conductive pad being higher than or coplanar with a lower surface of the recess; and
a second protective pattern on the insulation layer, the second protective pattern having an opening connected to the recess.

2. The package substrate according to claim 1, wherein an upper surface of the first wiring is coplanar with the lower surface of the recess.

3. The package substrate according to claim 1, wherein an upper surface of the first wiring is higher than the lower surface of the recess.

4. The package substrate according to claim 3, wherein a thickness in a vertical direction of the first wiring is in a range of about 8 μm to about 20 μm, and a thickness in the vertical direction of the conductive pad is in a range of about 2.3 μm to about 11.0 μm, and
wherein the upper surface of the first wiring is higher than an upper surface of the portion of the insulation layer by about 3 μm to about 5 μm.

5. The package substrate according to claim 1, wherein the conductive pad has a flat upper surface.

6. The package substrate according to claim 1, wherein an upper surface of the conductive pad is lower than an upper surface of a portion of the insulation layer on which the recess is not disposed.

7. The package substrate according to claim 1, wherein a sidewall of the conductive pad is aligned with a sidewall of the first wiring in a vertical direction.

8. The package substrate according to claim 1, wherein a sidewall of the opening is aligned with a sidewall of the recess in a vertical direction.

9. The package substrate according to claim 1, wherein the conductive pad includes first and second conductive patterns stacked in a vertical direction, the first and second conductive patterns including different metals from each other.

10. The package substrate according to claim 1, further comprising a second wiring spaced apart from the first wiring in a horizontal direction and buried in the insulation layer,
wherein an upper surface of the second wiring is lower than an upper surface of a portion of the insulation layer surrounding the second wiring.

11. The package substrate according to claim 10, wherein a lower surface of the second wiring is coplanar with a lower surface of the first wiring.

12. The package substrate according to claim 1, wherein each of the first and second protective patterns includes solder resist (SR), and the insulation layer includes prepreg (PPG) or Ajinomoto build-up film (ABF).

13. A package substrate comprising:
a first protective pattern;
an insulation layer structure including insulation layers stacked in a vertical direction on the first protective pattern;
a wiring structure including wirings disposed in the vertical direction in the first protective pattern and the insulation layer structure; and
a second protective pattern on the insulation layer structure and the wiring structure,
wherein:
first and second wirings among the wirings are buried in a first insulation layer that is an uppermost one of the insulation layers, and an upper surface of each of the first and second wirings is lower than an upper surface of the first insulation layer,
the second protective pattern covers the upper surface of the first wiring and exposes the upper surface of the second wiring,
the package substrate further comprises a first conductive pad on the second wiring having an upper surface lower than the upper surface of the first insulation layer, and
a portion of the first insulation layer adjacent to the first conductive pad has a recess exposing a sidewall of the first conductive pad.

14. The package substrate according to claim 13, wherein the recess exposes an upper sidewall of the second wiring.

15. The package substrate according to claim 13, wherein the sidewall of the first conductive pad is aligned with a sidewall of the second wiring in a vertical direction.

16. The package substrate according to claim 13, wherein:
third and fourth wirings among the wirings are disposed on a lower surface of a second insulation layer that is a lowermost one of the insulation layers,
the third wiring is covered by the first protective pattern,
the package substrate further comprises a second conductive pad on a sidewall and a lower surface of the fourth wiring, and
a sidewall of the second conductive pad is covered by the first protective pattern.

17. The package substrate according to claim 16, wherein the first conductive pad includes first and second conductive patterns sequentially stacked in the vertical direction on the upper surface of the second wiring, the first and second conductive patterns including first and second metals, respectively, and
wherein the second conductive pad includes third and fourth conductive patterns sequentially stacked in the vertical direction on the sidewall and the lower surface of the fourth wiring, the third and fourth conductive patterns including the first and second metals, respectively.

18. A semiconductor package comprising:
a package substrate including:
a first protective pattern;
an insulation layer on the first protective pattern, the insulation layer having a recess thereon;
a first wiring buried at a portion of the insulation layer on which the recess is disposed;
a first conductive pad on the first wiring, a lower surface of the first conductive pad being higher than or coplanar with a lower surface of the recess; and
a second protective pattern on the insulation layer, the second protective pattern having an opening connected to the recess;
a semiconductor chip on the package substrate, the semiconductor chip having a second conductive pad;
a bonding wire contacting an upper surface of the first conductive pad and an upper surface of the second conductive pad; and
a molding member on the package substrate, the molding member covering the semiconductor chip and the bonding wire and filling the recess and the opening.

19. The semiconductor package according to claim 18, wherein a sidewall of the first conductive pad is aligned with a sidewall of the first wiring in a vertical direction.

20. The package substrate according to claim 18, further comprising a second wiring in the insulation layer, the second wiring being spaced apart from the first wiring in a horizontal direction,
wherein an upper surface of the second wiring is lower than a portion of the insulation layer surrounding the second wiring, and a lower surface of the second wiring is coplanar with a lower surface of the first wiring.
